(19) United States
(12) Patent Application Publication
(10) Pub. No.: US 2026/0334274 A1
(43) Pub. Date: Oct. 22, 2026

(54) METHOD FOR PRODUCING AN ELECTRONIC COMPONENT, AND ELECTRONIC COMPONENT

(71) Applicant: ams-OSRAM International GmbH, Regensburg (DE)

(72) Inventor: Thomas Schwarz, Regensburg (DE)

(21) Appl. No.: 19/110,392

(22) PCT Filed: Sep. 12, 2023
(86) PCT No.: PCT/EP2023/074970

§ 371 Date: Mar. 10, 2025

(30) Foreign Application Priority Data
Sep. 23, 2022 (DE) 10 2022 124 574.8

(51) Int. Cl. H10W 72/00; H10H 20/01; H10H 20/857; H10W 72/30; H10W 72/90

(52) U.S. Cl. CPC H10W 72/07352; H10H 20/0364; H10H 20/857; H10W 72/01325; H10W 72/01355; H10W 72/07332; H10W 72/07336; H10W 72/352; H10W 72/934

(57) ABSTRACT

In an embodiment a method for producing an electronic component includes providing an electronic semiconductor chip, forming a first contact pad and a second contact pad on a contact side of the electronic semiconductor chip, wherein the first contact pad and the second contact pad are raised by a first height above a section of the contact side that is located between the first contact pad and the second contact pad, providing a carrier, forming a first mating contact pad and a second mating contact pad on a top side of the carrier, wherein the first mating contact pad and the second mating contact pad are raised by a second height above a section of the top side of the carrier that is located between the first mating contact pad and the second mating contact pad, wherein the first height is greater than or equal to zero and the second height is greater than, smaller than or equal to zero, and wherein a total height formed as a sum of the first height and the second height is greater than zero, and arranging capsules on the mating contact pads.

### CROSS-REFERENCE TO RELATED APPLICATIONS

This patent application is a national phase filing under section 371 of PCT/EP 2023/074970, filed Sep. 12, 2023, which claims the priority of German patent application no. 10 2022 124 574.8, filed Sep. 23, 2022, each of which is incorporated herein by reference in its entirety.

### TECHNICAL FIELD

The present invention relates to a method for producing an electronic component and an electronic component.

### BACKGROUND

Various methods for electrically contacting electronic semiconductor chips with small lateral dimensions are known in the prior art. Many methods of this type necessitate a prior microstructuring of the contact materials that are used and are associated with a high risk of short circuit.

### SUMMARY

Embodiments provide a method for producing an electronic component. Further embodiments provide an electronic component.

One method for producing an electronic component comprises steps for providing an electronic semiconductor chip, wherein a first contact pad and a second contact pad are formed on a contact side of the electronic semiconductor chip, wherein the first contact pad and the second contact pad are raised by a first height above a section of the contact side that is located between the first contact pad and the second contact pad, for providing a carrier, wherein a first mating contact pad and a second mating contact pad are formed on a top side of the carrier, wherein the first mating contact pad and the second mating contact pad are raised by a second height above a section of the top side of the carrier that is located between the first mating contact pad and the second mating contact pad, wherein the first height is greater than or equal to zero and the second height is greater than, smaller than or equal to zero, wherein a total height formed as the sum of the first height and the second height is greater than zero, for arranging capsules on the mating contact pads, wherein the capsules each comprise a solid shell that encloses a supercooled metallic liquid, wherein the capsules each comprise a diameter that is smaller than the total height, and for pressing the electronic semiconductor chip onto the carrier in such a manner that the contact pads of the electronic semiconductor chip are pressed onto the mating contact pads of the carrier, wherein the shells of the capsules that are arranged between the contact pads and the mating contact pads break open and the metallic liquid wets the contact pads and the mating contact pads.

This method does not necessitate any fine structuring of a connecting material for connecting the contact pads of the electronic semiconductor chip to the mating contact pads of the carrier. As a result, the method can advantageously be carried out in a simple and cost-effective manner. The method additionally does not require the use of silver to produce the electrically conductive connection between the electronic semiconductor chip and the carrier, as a result of which the risk of migration of silver and the danger of short circuits, which is associated with that, are advantageously reduced. The method also does not require a prior application of solder onto the contact pads of the electronic semiconductor chip, which likewise contributes to it being possible to carry out the method in a simple and cost-effective manner. Furthermore, the method can be carried out at low temperatures, which inter alia allows the use of inexpensive carrier materials, for example the use of PET.

In one embodiment of the method, capsules are also arranged on a section of the top side of the carrier, which is located next to the mating contact pads. This makes it possible to deposit the capsules using a method with low positional accuracy, as a result of which the method can be carried out in a simple and cost-effective manner.

In one embodiment of the method, following the pressing-on of the electronic semiconductor chip, a further step is carried out to remove at least a portion of the capsules arranged next to the mating contact pads. This advantageously prevents capsules that are arranged next to the mating contact pads from breaking open, for example due to the effect of heat, at a time following the pressing of the electronic semiconductor chip onto the carrier, and causing electrical short circuits.

In one embodiment of the method, the removal of the capsules takes place using a solvent, by blowing off, by an etching method or using an adhesive film. Advantageously, these variants each enable an effective, gentle and cost-effective removal of at least a portion of the capsules that are arranged next to the mating contact pads.

In one embodiment of the method, the arrangement of the capsules takes place using a shadow mask. This advantageously enables a simple and cost-effective deposition of the capsules, wherein the positions of the capsules can be limited to desired regions of the top side of the carrier.

In one embodiment of the method, the arrangement of the capsules takes place using a spray method. A fast and cost-effective deposition of the capsules is advantageously possible as a result of this.

In one embodiment of the method, the capsules are arranged together with a solvent on the mating contact pads. The solvent evaporates prior to the pressing-on of the electronic semiconductor chip. Capsules that are dispersed in a solvent can advantageously be deposited particularly well using a spray method.

In one embodiment of the method, the arrangement of the capsules takes place using a printing method. A printing method advantageously also enables a cost-effective deposition of the capsules onto the top side of the carrier.

In one embodiment of the method, the capsules are arranged embedded in a matrix material on the mating contact pads. Capsules that are embedded in a matrix material can advantageously be arranged particularly simply on the mating contact pads of the carrier. The matrix material may for example be an organic material or comprise an acrylic resin, an epoxide or a silicone.

In one embodiment of the method, the matrix material is removed after the pressing-on of the electronic semiconductor chip, particularly using a solvent. Advantageously, capsules that are arranged next to the mating contact pads can also be removed when removing the matrix material.

In one embodiment of the method, the matrix material is cured after the pressing-on of the electronic semiconductor chip. The matrix material can then remain on the electronic component that can be obtained using the method. The cured matrix material can protect capsules that have remained in the matrix material and isolate them from one another, so that capsules that have remained in the matrix material cannot cause undesirable short circuits even after the pressing of the electronic semiconductor chip onto the carrier.

In one embodiment of the method, following the pressing-on of the electronic semiconductor chip, the matrix material touches the section of the contact side of the electronic semiconductor chip that is located between the first contact pad and the second contact pad and the section of the top side of the carrier that is located between the first mating contact pad and the second mating contact pad. The cured matrix material can form an underfill of the electronic semiconductor chip as a result and additionally mechanically fix the same on the carrier. The underfill can also protect the electrically conductive connections between the electronic semiconductor chip and the carrier from external influences.

In one embodiment of the method, a spacing between the first contact pad and the second contact pad is less than 50 μm, particularly less than 20 μm. Advantageously, in spite of this only small space between the contact pads of the electronic semiconductor chip, the method enables reliable electrical contacting without the danger of a short circuit between the first contact pad and the second contact pad.

In one embodiment of the method, the diameter of the capsules is between 0.2 μm and 10 μm, particularly between 0.5 μm and 5 μm. As a result, the capsules are advantageously suitable for producing an electrically conductive connection between the contact pads of the electronic semiconductor chip and the mating contact pads of the carrier even in the case of a very small electronic semiconductor chip with very small contact pads with very small spacing.

In one embodiment of the method, the diameter of the capsules is between 0.5 μm and 3 μm smaller than the total height. As a result, the method advantageously enables production of an electronic component with very compact external dimensions, particularly with a small height.

In one embodiment of the method, the shells of the capsules comprise an oxide, particularly a tin oxide (SnOx). As a result, the shells of the capsules advantageously comprise suitable mechanical properties.

In one embodiment of the method, the supercooled metallic liquid comprises Sn, SnAgCu or SnBi. As a result, the supercooled metallic liquid is advantageously suitable for producing an electrically conductive connection between the contact pads of the electronic semiconductor chip and the mating contact pads of the carrier.

In one embodiment of the method, the electronic semiconductor chip is an optoelectronic semiconductor chip, particularly a light-emitting diode chip. As a result, the method is suitable for producing an optoelectronic component, for example a light-emitting diode component. Advantageously, optoelectronic semiconductor chips with a very small size can be used in this case.

An electronic component comprises an electronic semiconductor chip and a carrier. A first contact pad and a second contact pad are formed on a contact side of the electronic semiconductor chip. The first contact pad and the second contact pad are raised by a first height above a section of the contact side that is located between the first contact pad and the second contact pad. A first mating contact pad and a second mating contact pad are formed on a top side of the carrier. The first mating contact pad and the second mating contact pad are raised by a second height above a section of the top side of the carrier that is located between the first mating contact pad and the second mating contact pad. The first height is greater than or equal to zero. The second height is greater than, smaller than or equal to zero. A total height formed as the sum of the first height and the second height is greater than zero. The first contact pad and the second contact pad are connected via soldered connections to the first mating contact pad and the second mating contact pad. Capsules are arranged on the section of the top side of the carrier that is located between the first mating contact pad and the second mating contact pad, which capsules each comprise a solid shell that encloses a supercooled metallic liquid. The capsules each comprise a diameter that is smaller than the total height.

This electronic component can advantageously be produced in a simple and cost-effective manner. The soldered connections can be formed without silver, as a result of which the risk of migration of silver and the danger of short circuits, which is associated with that, can advantageously be reduced. The carrier can comprise a cost-effective carrier material, for example PET.

In one embodiment of the electronic component, the capsules are embedded in a matrix material. The matrix material can protect the capsules that are embedded in the matrix material and isolate them from one another, so that the capsules advantageously cannot cause undesirable short circuits. The matrix material can also form an underfill of the electronic semiconductor chip, additionally mechanically fix the same on the carrier and protect the soldered connections between the electronic semiconductor chip and the carrier from external influences.

### BRIEF DESCRIPTION OF THE DRAWINGS

The above-described properties, features and advantages of this invention and the manner in which these are achieved become clearer and more clearly understandable in connection with the following description of the exemplary embodiments that are explained in more detail in connection with the drawings.

FIG. 1 shows a sectional side view of an electronic semiconductor chip;

FIG. 2 shows a sectional side view of a carrier;

FIG. 3 shows a plan view of mating contact pads on a top side of the carrier;

FIG. 4 shows a total height formed as the sum of a first height and a second height;

FIG. 5 shows a shadow mask that is used for depositing capsules;

FIG. 6 shows a side view of the carrier with the capsules deposited on the mating contact pads;

FIG. 7 shows a plan view of the top side of the carrier with the capsules deposited thereon;

FIG. 8 shows a sectional view of one of the capsules;

FIG. 9 shows a sectional side view of the carrier with electronic semiconductor chip pressed thereon;

FIG. 10 shows a sectional detail view of a contact pad and a mating contact pad during the pressing-on of the electronic semiconductor chip;

FIG. 11 shows a further detail view of a contact pad and a mating contact pad during the pressing-on of the electronic semiconductor chip;

FIG. 12 shows capsules that are embedded in a solvent; and

FIG. 13 shows the carrier, the electronic semiconductor chip and capsules that are embedded in a matrix material.

### DETAILED DESCRIPTION OF ILLUSTRATIVE EMBODIMENTS

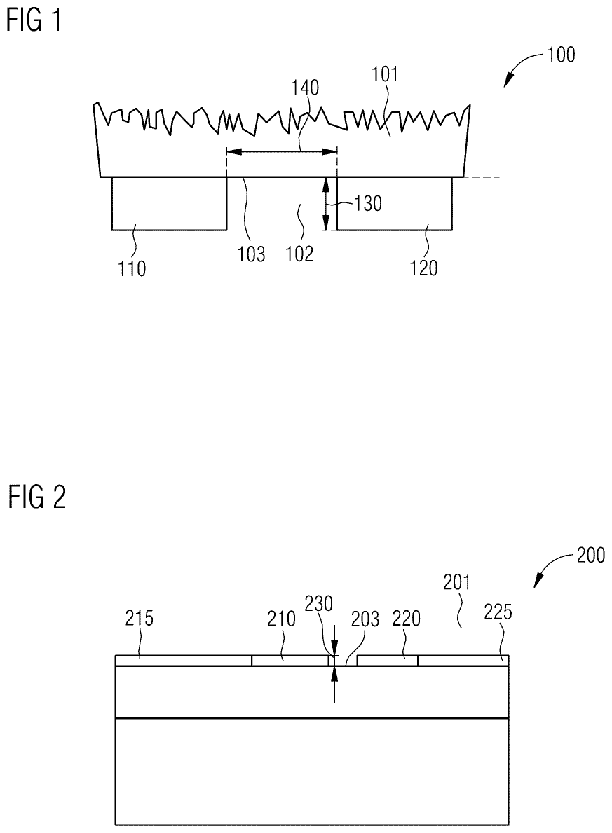

FIG. 1 shows a schematic sectional side view of an electronic semiconductor chip 100. The electronic semiconductor chip 100 can for example be an optoelectronic semiconductor chip, particularly a light-emitting diode chip (LED chip) for example. The electronic semiconductor chip 100 can however also be any desired other electronic semiconductor chip.

The electronic semiconductor chip 100 comprises a front side 101 and a contact side 102 opposite the front side 101. If the electronic semiconductor chip 100 is formed as an optoelectronic semiconductor chip, the front side 101 can for example form a light-emitting side of the electronic semiconductor chip 100. In the case of a differently formed electronic semiconductor chip 100, the front side 101 can comprise a different or even no functional property.

A first contact pad 110 and a second contact pad 120 are formed on the contact side 102 of the electronic semiconductor chip 100. The first contact pad 110 and the second contact pad 120 are provided to electrically contact the electronic semiconductor chip 100, for example in order to load the electronic semiconductor chip 100 with electric voltage and electric current. The contact pads 110, 120 can for example be formed as sequences of layers of different metallic materials.

The first contact pad 110 and the second contact pad 120 comprise a spacing 140 from one another that is measured in the lateral direction. In the case of a small electronic semiconductor chip 100, the spacing 140 can likewise be small. The spacing 140 can for example be less than 50 μm or even less than 20 μm.

The first contact pad 110 and the second contact pad 120 are each raised by a first height 130 above a section 103 of the contact side 102 of the electronic semiconductor chip 100 that is located between the first contact pad 110 and the second contact pad 120. The first height 130 is dimensioned perpendicularly to the contact side 102 in this case. The first height 130 can lie in the range of a few μm and be for example up to 10 μm. The first height 130 can however also amount to smaller values down to below 1 μm. In an extreme case, the first height 130 may even be equal to zero. In this case, the first contact pad 110 and the second contact pad 120 are not at all raised above the section 103 of the contact side 102 that is located between the contact pads 110, 120, but rather terminate flush with the contact side 102 of the electronic semiconductor chip 100.

The electronic semiconductor chip 100 can additionally comprise further contact pads in addition to the first contact pad 110 and the second contact pad 120.

FIG. 2 shows a schematic sectional side view of a carrier 200. The carrier 200 can also be termed a substrate. The carrier 200 can for example comprise a plastic material, particularly PET for example.

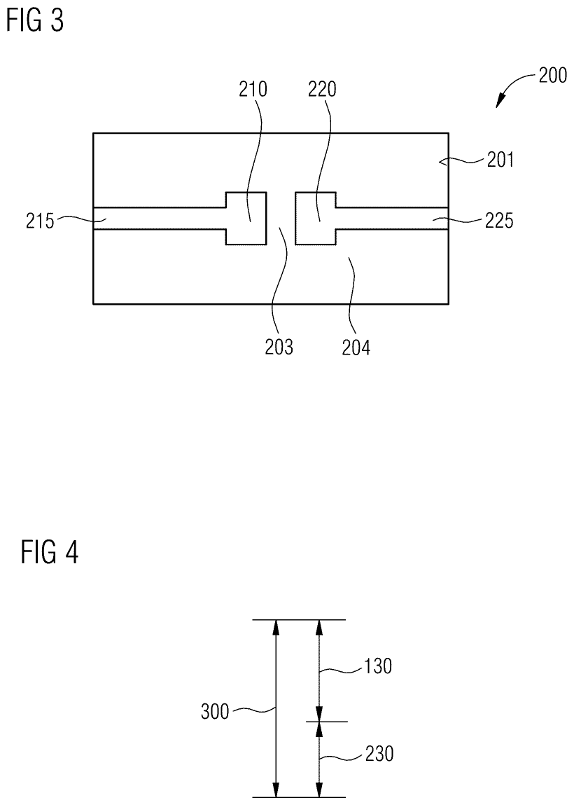

The carrier 200 comprises a top side 201 that is illustrated in plan view in FIG. 3. A first mating contact pad 210 and a second mating contact pad 220 are formed on the top side 201 of the carrier 200. The first mating contact pad 210 is electrically conductively connected to a first conductor track 215 that is arranged on the top side 201. The second mating contact pad 220 is electrically conductively connected to a second conductor track 225 that is formed on the top side 201. The first mating contact pad 210 and the second mating contact pad 220 can for example each be formed as a layer stack of different metallic materials.

The first mating contact pad 210 and the second mating contact pad 220 are raised by a second height 230 above a section 203 of the top side 201 of the carrier 200 that is located between the first mating contact pad 210 and the second mating contact pad 220. The second height 230 is dimensioned perpendicularly to the top side 201 of the carrier 200 in this case.

The second height 230 can for example be a few μm and is for example up to 10 μm. The second height 230 can however also comprise a smaller value, for example a value of less than 1 μm. The first mating contact pad 210 and the second mating contact pad 220 can even be sunk into the top side 201 of the carrier 200 in such a manner that the second height 230 is equal to zero or even comprises a value of less than zero. In the last-mentioned case, the section 203 of the top side 201 of the carrier 200 that is located between the first mating contact pad 210 and the second mating contact pad 220 stands out above the first mating contact pad 210 and the second mating contact pad 220.

The first conductor track 215 and the second conductor track 225 can comprise a height with respect to the top side 201 of the carrier 200 which corresponds to the second height 230 of the first mating contact pad 210 and the second mating contact pad 220. The conductor tracks 215, 225 can however also comprise a smaller or a larger height.

The carrier 200 can additionally comprise further mating contact pads in addition to the first mating contact pad 210 and the second mating contact pad 220.

From the first height 130 of the contact pads 110, 120 of the electronic semiconductor chip 100 and the second height 230 of the mating contact pads 210, 220 of the carrier 200, it is possible to form a total height 300 arithmetically by addition. This is illustrated graphically in FIG. 4. The total height 300 corresponds to the sum of the first height 130 and the second height 230. This is true not only for the case, shown in FIG. 4, that the first height 130 and the second height 230 each comprise positive values, but also in the case that the first height 130 or the second height 230 comprises the value zero or the second height 230 has a negative value.

FIG. 5 shows a schematic illustration of the top side 201 of the carrier 200 with a shadow mask 500 that is arranged above the top side 201. The shadow mask 500 comprises an opening 510 that is arranged above the first mating contact pad 210 and the second mating contact pad 220. In the illustrated example, the size of the opening 510 is dimensioned such that, apart from the first mating contact pad 210 and the second mating contact pad 220 and the section 203 of the top side 201 of the carrier 200 that is located between the mating contact pads 210, 220, parts of the conductor tracks 215, 225 and further sections 204 of the top side 201 of the carrier 200 are also visible and accessible through the opening 510.

The opening 510 of the shadow mask 500 could however also be dimensioned so small for example that only the first mating contact pad 210, the second mating contact pad 220 and the section 203 of the top side 201 of the carrier 200 that is located between the mating contact pads 210, 220 are exposed. Alternatively, the opening 510 of the shadow mask 500 could also be larger. The use of a shadow mask 500 with a larger opening 510 offers the advantage that the shadow mask 500 only has to be positioned with little accuracy in order to arrange the opening 510 above the first mating contact pad 210 and the second mating contact pad 220. The use of the shadow mask 500 can also be dispensed with entirely, as is also explained in the following.

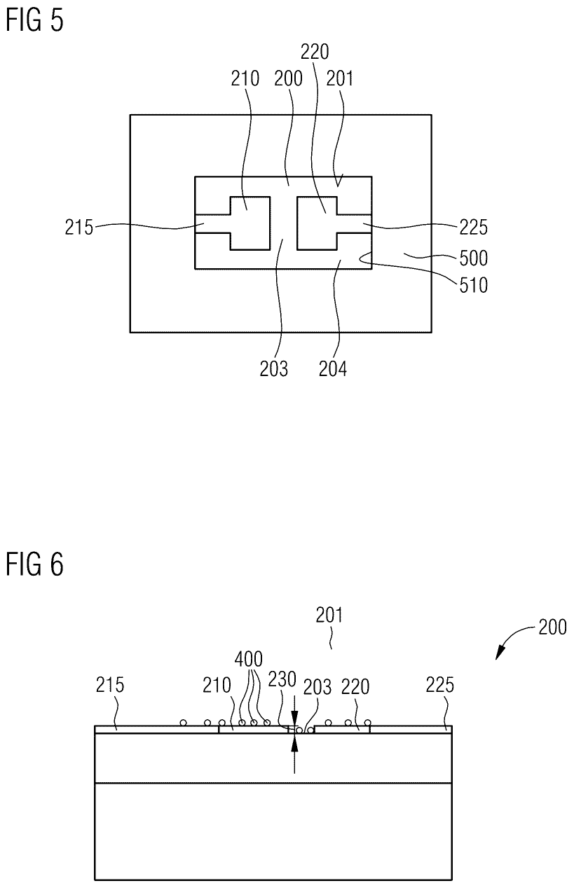

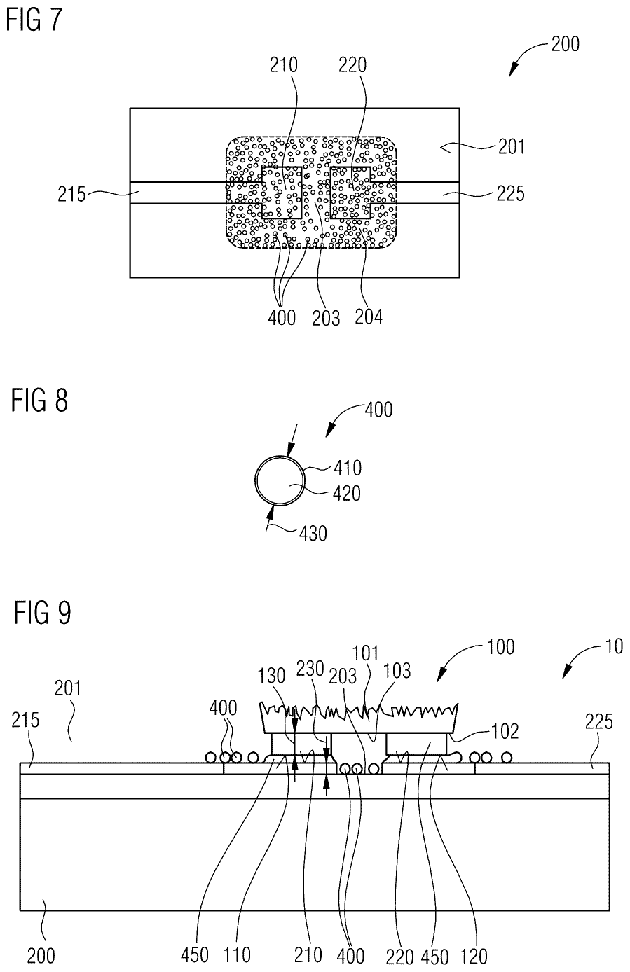

FIG. 6 shows a schematic sectional side view of the carrier 200 in a processing state following the previous illustrations in time. FIG. 7 shows a plan view of the top side 201 of the carrier 200 in the processing state illustrated in FIG. 6.

Capsules 400 have been arranged on the mating contact pads 210, 220 on the top side 201 of the carrier 200. The arrangement of the capsules 400 has taken place using the shadow mask 500 shown in FIG. 5. In this case, capsules 400 have been arranged in the entire region exposed by the opening 510 of the shadow mask 500. As a result, capsules 400 have been arranged not only on the first mating contact pad 210 and the second mating contact pad 220, but rather also on the section 203 of the top side 201 of the carrier 200 that is located between the mating contact pads 210, 220, on parts of the conductor tracks 215, 225 and on further sections 204 of the top side 201 of the carrier 200. By using a shadow mask 500 with a smaller opening 510, the capsules 400 could however also be limited to the first mating contact pad 210, the second mating contact pad 220 and the section 203 of the top side 201 of the carrier 200 that is located between the mating contact pads 210, 220. If a shadow mask 500 were dispensed with entirely, the capsules 400 would be arranged on the entire top side 201 of the carrier 200. What is absolutely necessary is merely that capsules 400 are arranged on the mating contact pads 210, 220.

The capsules 400 are all formed in essentially the same manner. FIG. 8 shows a schematic sectional view of one of the capsules 400. Each capsule 400 comprises a solid shell 410 that encloses a supercooled metallic liquid 420. The solid shell 410 can for example comprise an oxide in this case, for example a tin oxide (SnOx, SnO, Sn₂O₃, SnO₂). The supercooled metallic liquid 420 can for example comprise tin or a tin compound, particularly for example Sn, SnAgCu or SnBi.

The capsules 400 each comprise a diameter 430. The diameter 430 is smaller than the total height 300, that is to say smaller than the sum of the first height 130 and the second height 230. It is expedient that the diameter 430 of the capsules 400 is between 0.5 μm and 3 μm smaller than the total height 300. The diameter 430 of the capsules 400 can for example be between 0.2 μm and 10 μm, particularly between 0.5 μm and 5 μm for example.

FIG. 9 shows a schematic sectional side view of the electronic semiconductor chip 100 and the carrier 200 in a processing state following the previous illustrations in time.

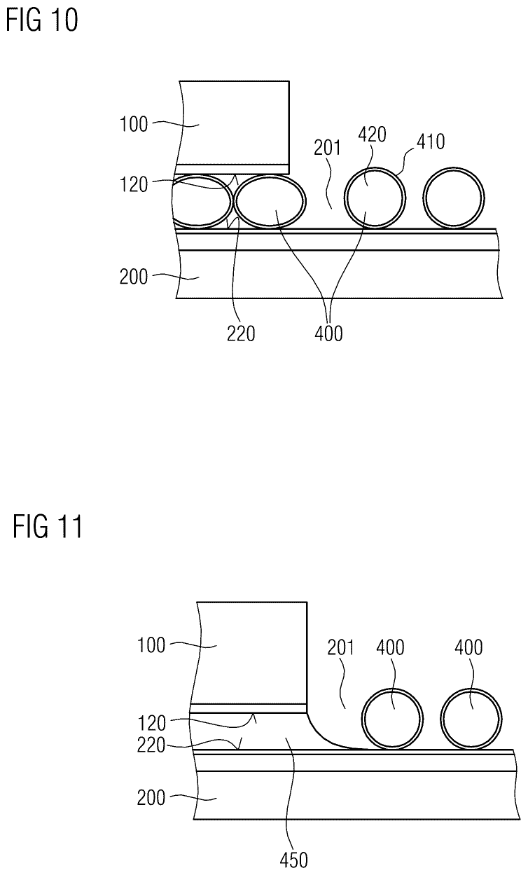

In a processing step preceding the illustration of FIG. 9 in time, the electronic semiconductor chip 100 has been pressed onto the carrier 200 in such a manner that the first contact pad 110 of the electronic semiconductor chip 100 has been pressed onto the first mating contact pad 210 of the carrier 200 and the second contact pad 120 of the electronic semiconductor chip 100 has been pressed onto the second mating contact pad 220 of the carrier 200. This processing step is shown schematically in FIG. 10, where an enlarged sectional side view of part of the second contact pad 120 of the electronic semiconductor chip 100 and part of the second mating contact pad 220 of the carrier 200 is illustrated. Due to the pressing of the electronic semiconductor chip 100 onto the carrier 200, the capsules 400 previously arranged on the mating contact pads 210, 220 are crushed and deformed between the mating contact pads 210, 220 and the contact pads 110, 120 until the shells 410 of the capsules 400 that are arranged between the contact pads 110, 120 and the mating contact pads 210, 220 finally break open. Then, the supercooled metallic liquid 420 contained in the capsules 400 runs out and wets the contact pads 110, 120 of the electronic semiconductor chip 100 and the mating contact pads 210, 220 of the carrier 200. The pressing of the electronic semiconductor chip 100 onto the carrier 200 can to this end take place for example with a pressure between 0.1 MPa and 10 MPa.

The supercooled metallic liquid 420 escaping from the capsules 400 that have broken open solidifies quickly after the wetting of the contact pads 110, 120 and mating contact pads 210, 220 and forms soldered connections 450 between the first contact pad 110 and the first mating contact pad 210 and the second contact pad 120 and the second mating contact pad 220. This is shown in FIG. 9 and in the enlarged detail view of FIG. 11.

The number of capsules 400 deposited onto the top side 201 of the carrier 200 per unit area during the arrangement of the capsules 400 on the mating contact pads 210, 220 of the carrier 200 can be chosen to be so high that the resulting soldered connections 450 comprise good electrical and thermal conductivity. At the same time, the number of capsules 400 per unit area should be chosen to be sufficiently low so that the soldered connections 450 transmit thermomechanical stress to the smallest possible extent and only a small risk of formation of an electrical short circuit arises during the pressing of the electronic semiconductor chip 100 onto the carrier 200.

As can be seen in FIGS. 9 and 11, the capsules 400 arranged on the section 203 of the upper side 201 of the carrier 200 that is located between the first mating contact pad 210 and the second mating contact pad 220 are not opened during the pressing of the electronic semiconductor chip 100 onto the carrier 200. This is ensured in particular in that the diameter 430 of the capsules 400 is smaller than the total height 300. Thus, undesirable short circuits between the first mating contact pad 210 and the second mating contact pad 220 of the carrier 200 or between the first contact pad 110 and the second contact pad 120 of the electronic semiconductor chip 100 are prevented from forming. Also, the capsules 400 that are arranged on the conductor tracks 215, 225 and on further sections 204 of the top side 201 of the carrier 200 remain undamaged.

In the processing state shown in FIG. 9, the carrier 200 with the electronic semiconductor chip 100 arranged thereon can form an electronic component 10, the processing of which is complete. If the electronic semiconductor chip 100 is an optoelectronic semiconductor chip, the electronic component 10 is an optoelectronic component. However, yet further processing steps can also take place, starting from the processing state shown in FIG. 9.

A process step for removing at least a portion of the capsules 400 arranged next to the mating contact pads 210, 220 can optionally follow the processing state shown in FIG. 9. In this case, some or all of the capsules 400 arranged on the top side 201 of the carrier 200 which have not been broken open during the pressing-on of the electronic semiconductor chip 100 are removed. The removal of these capsules 400 prevents these capsules 400 from breaking open at a later time, which could result in the supercooled metallic liquid 420 contained in the capsules 400 causing a short circuit. The capsules 400 breaking open later could for example be caused by mechanical stresses or by the effects of heat.

The removal of at least a portion of the capsules 400 arranged next to the mating contact pads 210, 220 can for example take place using a solvent, by blowing off, by an etching method or using an adhesive film. It is beneficial if when removing the capsules 400, a largest possible proportion is removed of the capsules 400 which are located on the section 203 of the top side 201 of the carrier 200 that is arranged between the mating contact pads 210, 220, as the capsules 400 arranged there could particularly easily cause a short circuit.

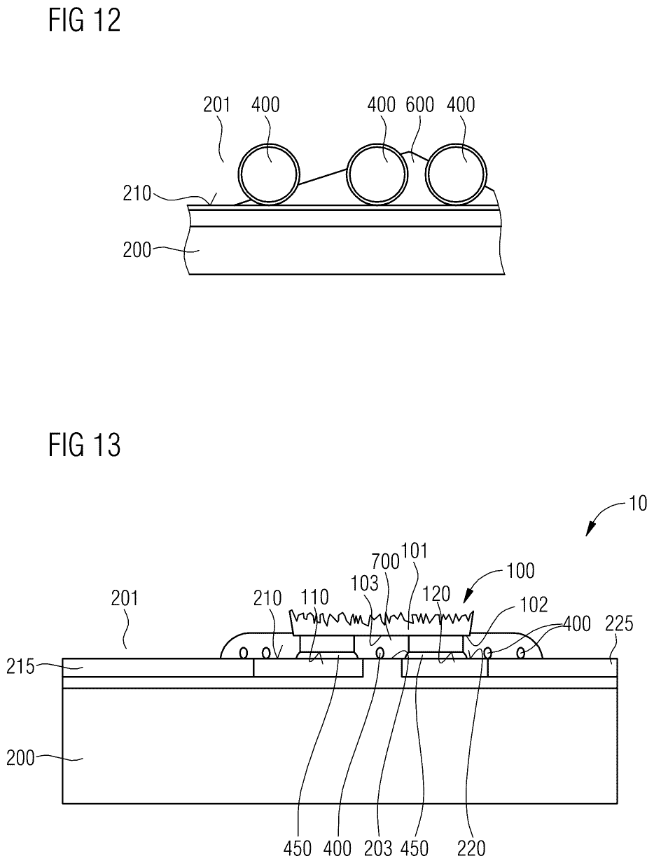

The arrangement of the capsules 400 on the mating contact pads 210, 220 of the carrier 200, which is described with reference to FIGS. 6 and 7, can take place for example using a spray method. The shadow mask 500 described with reference to FIG. 5 can optionally be used in this case. For spraying onto the top side 201 of the carrier 200, the capsules 400 can be dispersed in a solvent 600 that is sprayed on together with the capsules 400. This is illustrated schematically in FIG. 12, where part of the first mating contact pad 210 of the carrier 200 is illustrated with a few capsules 400 arranged thereon. The solvent 600 can evaporate after the spraying on of the capsules 400, before the electronic semiconductor chip 100 is pressed onto the carrier 200.

Alternatively, the arrangement of the capsules 400 can take place using a printing method which is described with reference to FIGS. 6 and 7. The shadow mask 500 described with reference to FIG. 5 can be used in this case for example. The shadow mask is a printing screen or a printing stencil in this case.

To arrange the capsules 400 using a printing method, the capsules 400 can be embedded in a matrix material 700. This is shown in FIG. 13, where the carrier 200 and the electronic semiconductor chip 100 are illustrated schematically after the pressing-on of the electronic semiconductor chip 100.

In a variant of the method, the matrix material 700 that is deposited together with the capsules 400 by a printing method can be removed, for example using a solvent, after the pressing-on of the electronic semiconductor chip 100. In this case, the matrix material 700 can for example comprise an organic material, for example a palmitic acid or 1-Decanol. Capsules 400 that are embedded in the matrix material 700 and were not broken open during the pressing-on of the electronic semiconductor chip 100 can also be removed during the removal of the matrix material 700.

One alternative possibility consists in curing the matrix material 700 after the pressing-on or during the pressing-on of the electronic semiconductor chip 100. In this case, the matrix material 700 can for example comprise an acrylic resin, an epoxide or a silicone. The curing of the matrix material 700 can for example take place by supplying heat or by irradiation with light. The cured matrix material 700 then remains on the electronic component 10, as is illustrated in FIG. 13.

The cured matrix material 700 can fix the capsules 400 that are embedded in the matrix material 700 and are not broken open during the pressing-on of the electronic semiconductor component 100 in such a manner that these capsules 400 are prevented from breaking open later or at least the occurrence of a short circuit due to the metallic liquid 420 escaping from the capsules 400 is prevented.

The cured matrix material 700 can also fulfil the function of an underfill. In this case, it is expedient if, following the pressing-on of the electronic semiconductor chip 100, the matrix material 700 touches the section 103 of the contact side 102 of the electronic semiconductor chip 100 that is located between the first contact pad 110 and the second contact pad 120 and the section 203 of the top side 201 of the carrier 200 that is located between the first mating contact pad 210 and the second mating contact pad 220. In this case, the matrix material 700 fills the space between the contact pads 110, 120, the contact side 102 of the electronic semiconductor chip 100, the mating contact pads 210, 220, and the top side 201 of the carrier 200 as completely as possible. The matrix material 700 then effects an additional mechanical fixing of the electronic semiconductor chip 100 on the carrier 200, can prevent ion migration and protects the electrical connections between the contact pads 110, 120 and the mating contact pads 210, 220 from external influences due to moisture, acids and corrosive gases.

The invention was illustrated and described in more detail with reference to the preferred exemplary embodiments. The invention is not limited to the disclosed examples, however. Different variations can be deduced by a person skilled in the art.

1-20. (canceled)

21. A method for producing an electronic component, the method comprising:
providing an electronic semiconductor chip;
forming a first contact pad and a second contact pad on a contact side of the electronic semiconductor chip, wherein the first contact pad and the second contact pad are raised by a first height above a section of the contact side that is located between the first contact pad and the second contact pad;
providing a carrier;
forming a first mating contact pad and a second mating contact pad on a top side of the carrier, wherein the first mating contact pad and the second mating contact pad are raised by a second height above a section of the top side of the carrier that is located between the first mating contact pad and the second mating contact pad,
wherein the first height is greater than or equal to zero and the second height is greater than, smaller than or equal to zero, and
wherein a total height formed as a sum of the first height and the second height is greater than zero;
arranging capsules on the mating contact pads, wherein each capsule comprises a solid shell that encloses a supercooled metallic liquid, and wherein each capsule comprises a diameter that is smaller than the total height; and
pressing the electronic semiconductor chip onto the carrier such that the contact pads of the electronic semiconductor chip are pressed onto the mating contact pads of the carrier,
wherein the shells of the capsules that are arranged between the contact pads and the mating contact pads break open and the metallic liquid wets the contact pads and the mating contact pads.

22. The method as claimed in claim 21, wherein the capsules are also arranged on a section of the top side of the carrier, which is located next to the mating contact pads.

23. The method as claimed in claim 22, further comprising, after pressing the electronic semiconductor chip onto the carrier, removing at least a portion of the capsules arranged next to the mating contact pads.

24. The method as claimed in claim 23, wherein removing comprises using a solvent, by blowing off, by an etching method or using an adhesive film.

25. The method as claimed in claim 21, wherein arranging the capsules on the mating contact pads comprises using a shadow mask.

26. The method as claimed in claim 21, wherein arranging the capsules on the mating contact pads comprises using a spray method.

27. The method as claimed in claim 21,
wherein the capsules are arranged together with a solvent on the mating contact pads, and
wherein the solvent evaporates prior to pressing the electronic semiconductor chip onto the carrier.

28. The method as claimed in claim 21, wherein arranging the capsules on the mating contact pads comprises using a printing method.

29. The method as claimed in claim 21, wherein the capsules are arranged embedded in a matrix material on the mating contact pads.

30. The method as claimed in claim 29, further comprising removing the matrix material after pressing the electronic semiconductor chip onto the carrier, wherein removing the matrix material comprises using a solvent.

31. The method as claimed in claim 29, further comprising curing the matrix material after pressing the electronic semiconductor chip onto the carrier.

32. The method as claimed in claim 31, wherein, after pressing the electronic semiconductor chip onto the carrier, the matrix material touches the section of the contact side of the electronic semiconductor chip that is located between the first contact pad and the second contact pad, and wherein the section of the top side of the carrier that is located between the first mating contact pad and the second mating contact pad.

33. The method as claimed in claim 21, wherein a spacing between the first contact pad and the second contact pad is less than 50 μm.

34. The method as claimed in claim 21, wherein a diameter of the capsules is between 0.2 μm and 10 μm, inclusive.

35. The method as claimed in claim 21, wherein a diameter of the capsules is between 0.5 μm and 3 μm smaller than the total height.

36. The method as claimed in claim 21, wherein the shells of the capsules comprise an oxide.

37. The method as claimed in claim 21, wherein the supercooled metallic liquid comprises Sn, SnAgCu or SnBi.

38. The method as claimed in claim 21, wherein the electronic semiconductor chip is an optoelectronic semiconductor chip.

39. An electronic component comprising:
an electronic semiconductor chip and a carrier,
wherein a first contact pad and a second contact pad are located on a contact side of the electronic semiconductor chip,
wherein the first contact pad and the second contact pad have a first height above a section of the contact side that is located between the first contact pad and the second contact pad,
wherein a first mating contact pad and a second mating contact pad are located on a top side of the carrier,
wherein the first mating contact pad and the second mating contact pad have a second height above a section of the top side of the carrier that is located between the first mating contact pad and the second mating contact pad,
wherein the first height is greater than or equal to zero and the second height is greater than, smaller than or equal to zero,
wherein a total height is a sum of the first height and the second height is greater than zero,
wherein the first contact pad and the second contact pad are connected via soldered connections to the first mating contact pad and the second mating contact pad,
wherein capsules are arranged on the section of the top side of the carrier that is located between the first mating contact pad and the second mating contact pad,
wherein each capsule comprises a solid shell that encloses a supercooled metallic liquid, and
wherein each capsule comprises a diameter that is smaller than the total height.

40. The electronic component as claimed in claim 39, wherein the capsules are embedded in a matrix material.
